(19) United States
(12) Patent Application Publication
(10) Pub. No.: US 2014/0042018 A1
(43) Pub. Date: Feb. 13, 2014

(54) SPUTTERING TARGET AND METHOD FOR USING THE SPUTTERING TARGET

(71) Applicant: Semiconductor Energy Laboratory Co., Ltd., Atsugi-shi (JP)

(72) Inventor: Shunpei YAMAZAKI, Setagaya (JP)

(73) Assignee: Semiconductor Energy Laboratory Co., Ltd., Atsugi-shi (JP)

(21) Appl. No.: 13/959,099

(22) Filed: Aug. 5, 2013

(30) Foreign Application Priority Data
Aug. 10, 2012 (JP) 2012-178380

(51) Int. Cl. C23C 14/34

(52) U.S. Cl. CPC C23C 14/3407
USPC 204/192.25; 204/298.13

(57) ABSTRACT

To provide a sputtering target with which a crystalline metal oxide film can be formed. The sizes of crystal grains or crystal regions of the metal oxide included in the sputtering target are made uniform. Further, the crystal grains or the crystal regions are made smaller. Specifically, the sputtering target includes a polycrystalline metal oxide in which an average of grain sizes of the crystal grains is greater than or equal to 0.1 μm and less than or equal to 3 μm and a standard deviation of the grain sizes of the crystal grains is less than or equal to ½ of the average of the grain sizes of the crystal grains. Alternatively, the sputtering target includes a metal oxide having a plurality of crystal regions in which c-axes are aligned perpendicularly to a surface.

### BACKGROUND OF THE INVENTION

1. Field of the Invention

The present invention relates to a sputtering target and a method for using the sputtering target. The present invention relates to a metal oxide film formed using the sputtering target.

In this specification, a semiconductor device generally refers to a device which can function by utilizing semiconductor characteristics; an electro-optical device, a semiconductor circuit, and an electronic device are all included in the category of the semiconductor device.

2. Description of the Related Art

Thin films of an insulating metal oxide, a conductive metal oxide, and a semiconductor metal oxide (also referred to as an oxide semiconductor) are used for a variety of products such as semiconductor devices.

A sputtering method has a variety of advantages such that a film having strong attachment to a substrate can be formed, film formation can be performed without changing the most of the composition of a sputtering target, and film thickness can be controlled with high accuracy only by controlling time. For example, it is widely used as a method for forming an oxide semiconductor including indium, gallium, and zinc (Patent Document 1). The oxide semiconductor film has attracted attention because of its properties such as carrier mobility higher than that of an amorphous silicon thin film and has been actively researched.

In a transistor using an oxide semiconductor film including indium, gallium, and zinc, although transistor characteristics can be obtained relatively easily, an amorphous oxide semiconductor film tends to be used and physical properties are unstable; thus, it has been difficult to ensure reliability of the transistor.

However, a result of recent research and development shows that using a crystalline oxide semiconductor film increases reliability of a transistor from the case of using an amorphous oxide semiconductor film (Non-Patent Document 1).

### REFERENCE

### Patent Document

[Patent Document] PCT International Publication No. WO 05/088726 Pamphlet

### Non-Patent Document

[Non-Patent Document 1] Shunpei Yamazaki, Jun Koyama, Yoshitaka Yamamoto, and Kenji Okamoto, “Research, Development, and Application of Crystalline Oxide Semiconductor”, SID 2012 DIGEST, pp. 183-186

### SUMMARY OF THE INVENTION

There is no limitation to an oxide semiconductor film, and if a crystalline metal oxide film can be formed by a sputtering method, the film is expected to be a conductive film having high conductivity, an insulating film having high withstand voltage, or the like, which enables a variety of applications of them.

An object of one embodiment of the present invention is to provide a sputtering target with which a crystalline metal oxide film can be formed. Another object of one embodiment of the present invention is to provide a method for forming a metal oxide film using the sputtering target.

In order to achieve the above objects, in one embodiment of the present invention, a polycrystalline target or a CAAC target described later is manufactured and the sizes of crystal grains or crystal regions of a metal oxide included in the target are made uniform. Further, the crystal grains or the crystal regions are made smaller.

Specifically, one embodiment of the present invention is a sputtering target including a polycrystalline metal oxide in which the average of grain sizes of crystal grains is greater than or equal to 0.1 μm and less than or equal to 3 μm and the standard deviation of the grain sizes of the crystal grains is less than or equal to ½ of the average of the grain sizes of the crystal grains.

One embodiment of the present invention is a sputtering target including a metal oxide having a plurality of crystal regions in which c-axes are aligned perpendicularly to a surface. The average of projected area diameters of the crystal regions is greater than or equal to 1 nm and less than or equal to 20 nm, and the standard deviation of the projected area diameters of the crystal regions is less than or equal to ½ of the average of the projected area diameters of the crystal regions.

In the above, in electron diffraction patterns of a first crystal region and a second crystal region, which have different directions of a-axes and b-axes, and a crystal region between the first crystal region and the second crystal region, included in the plurality of crystal regions, belt-shaped fluorescent spots may be observed in a region which connects a fluorescent spot in the first crystal region and a fluorescent spot in the second crystal region in the crystal region between the first crystal region and the second crystal region.

In the above, the metal oxide may include indium, gallium, and zinc.

In the above, among indium, gallium, and zinc, the proportion of gallium may be over 20 atomic %.

In the above, the crystal grains may be hexagonal crystals and the crystal regions may include hexagonal crystals.

In the above, the silicon content and the carbon content each may be lower than 1×10¹⁸ atoms/cm³.

One embodiment of the present invention is a method for forming a metal oxide film in which flat-plate-like sputtered particles are generated by collision of ions to have a projected area diameter of greater than or equal to 1 nm and less than or equal to 20 nm and are deposited.

According to one embodiment of the present invention, a sputtering target with which a crystalline metal oxide film can be formed can be provided. Further, a method for forming a metal oxide film using the sputtering target can be provided.

### BRIEF DESCRIPTION OF THE DRAWINGS

In the accompanying drawings:

FIGS. 1A and 1B illustrate a sputtering target of one embodiment of the present invention;

FIG. 2 is a flow chart showing an example of a method for manufacturing a sputtering target;

FIGS. 3A to 3D each illustrate an example of a method for manufacturing a sputtering target;

FIGS. 4A to 4C are schematic views illustrating a situation where a spattered particle is separated from a sputtering target;

FIG. 5 is a schematic view illustrating a situation where a spattered particle is separated from a sputtering target;

FIGS. 6A and 6B are schematic views illustrating a situation where a sputtered particle reaches a deposition surface and is deposited;

FIGS. 7A and 7B illustrate an example of a crystal structure of an In—Ga—Zn oxide;

FIG. 8 illustrates an example of a crystal structure of an In—Ga—Zn oxide;

FIGS. 9A and 9B are conceptual diagrams of an active matrix light-emitting device;

FIG. 10 is a conceptual diagram of an active matrix light-emitting device;

FIGS. 11A to 11E each illustrate an electronic device;

FIG. 12 is a transmission electron microscope image of a metal oxide; and

FIGS. 13A1, 13A2, 13B, 13C1, and 13C2 are nanobeam electron diffraction patterns of a metal oxide.

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details thereof can be modified in various ways. Therefore, the present invention is not construed as being limited to description of the embodiments. In describing structures of the present invention with reference to the drawings, the same reference numerals are used in common for the same portions in different drawings. Note that the same hatch pattern is applied to similar parts, and the similar parts are not especially denoted by reference numerals in some cases.

Note that the ordinal numbers such as “first” and “second” in this specification are used for convenience and do not denote the order of steps or the stacking order of layers. In addition, the ordinal numbers in this specification do not denote particular names which specify the present invention.

In this specification and the like, the size of a crystal grain or a crystal region means the size of a crystal grain or a crystal region which appears on a flat plane of a metal oxide. The size of a crystal grain or a crystal region which appears on a flat plane of a metal oxide can be measured using a backscattered electron image obtained by a scanning electron microscope, a transmission electron microscope image, or the like.

In this specification and the like, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

In this specification and the like, the trigonal and rhombohedral crystal systems are included in the hexagonal crystal system.

### Embodiment 1

In this embodiment, a target including a polycrystalline metal oxide according to one embodiment of the present invention is described.

### <Polycrystalline Target>

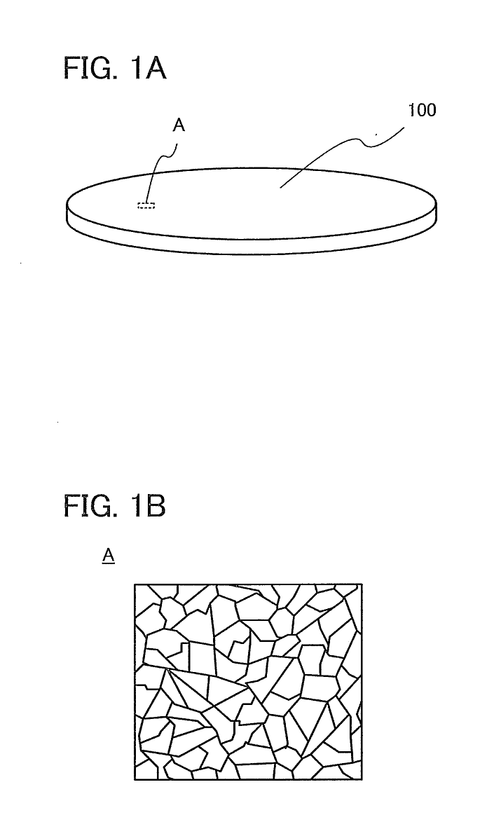

FIG. 1A illustrates a target 100 including a polycrystalline metal oxide according to one embodiment of the present invention, and FIG. 1B is an enlarged schematic view of a part A of the target 100. As illustrated in FIG. 1B, the target 100 includes a plurality of crystal grains. The grain sizes of the crystal grains are made uniform and the average grain size is reduced; thus, a crystalline metal oxide film can be formed.

Specifically, the average grain size of the crystal grains is preferably greater than or equal to 0.1 μm and less than or equal to 3 μm, more preferably greater than or equal to 0.1 μm and less than or equal to 0.5 μm.

Further, the standard deviation of the grain sizes of the crystal grains is preferably less than or equal to the average grain size of the crystal grains, more preferably less than or equal to ½ of, further more preferably less than or equal to ⅕ of the average grain size of the crystal grains. Further, the grain sizes of 68% of the crystal grains are preferably two times or less, more preferably 0.5 to 1.5 times, further more preferably 0.8 to 1.2 times as large as the average grain size of the crystal grains.

The composition of the metal oxide included in the target 100 can be determined as appropriate depending on a desired metal oxide film.

For example, in the case where an aim is to form an insulating metal oxide film, an oxide including gallium, hafnium, copper, iron, or the like can be used.

In the case where an aim is to form a conductive metal oxide film, indium tin oxide (also referred to as ITO) or the like can be used.

In the case where a semiconductor metal oxide film (oxide semiconductor film) is formed, a target preferably includes at least indium oxide or zinc oxide, more preferably includes both of indium oxide and zinc oxide. It is further more preferable that the target include at least one of gallium oxide, tin oxide, hafnium oxide, and aluminum oxide in addition to these. This is because when an oxide semiconductor film formed using such a target is applied to a transistor, variation in electric characteristics of the transistor can be reduced.

For example, a target including indium oxide, gallium oxide, and zinc oxide is preferably used because when the proportion of gallium oxide which is a stabilizer exceeds 20 atomic %, variation in electric characteristics of the transistor can be reduced. For example, a target having a composition ratio of indium:gallium:zinc of 1:1:1 (atomic ratio) or a composition ratio of indium:gallium:zinc of 1:3:2 (atomic ratio) is preferably used.

In a target including indium oxide, gallium oxide, and zinc oxide, the crystal grains are hexagonal crystals in some cases.

In the case where an aim is to form an oxide semiconductor film, when an impurity is included in a target, electric characteristics of a transistor including an oxide semiconductor film formed using the target might be adversely affected. Therefore, it is preferable that the impurity concentration in the target be reduced. As examples of the impurity in the target, silicon, carbon, nitrogen, boron, arsenic, another metal element involuntarily mixed, or the like can be given. In particular, it is revealed that silicon and carbon form impurity states in an oxide semiconductor film and make the oxide semiconductor film n-type, or serve as trap states. Thus, the silicon content and the carbon content in the target are each preferably less than 1×10¹⁸ atoms/cm³, more preferably less than 3×10¹⁷ atoms/cm³.

### <Method for Manufacturing Polycrystalline Target>

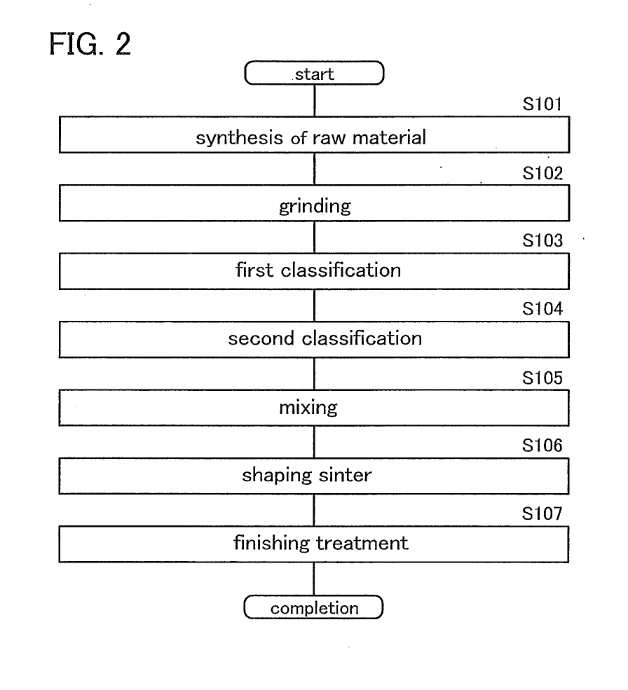

An example of a method for manufacturing the target 100 including a polycrystalline metal oxide is described with reference to FIG. 2. Here, although description is made using a target including indium oxide, gallium oxide, and zinc oxide as an example, a target having another composition can be manufactured in a similar manner by changing a raw material.

First, a metal oxide which is a raw material is synthesized in Step S101. In the case where a target including indium oxide, gallium oxide, and zinc oxide is manufactured, the raw material is an indium oxide powder, a gallium oxide powder, and a zinc oxide powder.

As a synthesis method of the raw material, a known method can be employed. For example, as one of synthesis methods of an metal oxide powder, there is a method in which a metal hydroxide is generated and precipitated by mixing an alkaline solution and a metal salt such as a nitrate or a sulfate to be naturalized, precipitation of the metal hydroxide is collected by filtration or the like, and then the metal hydroxide is baked to obtain gallium oxide.

Next, in Step S102, the raw material obtained in Step S101 is ground. At this time, the size of the grounded metal oxide powder preferably becomes less than or equal to 1 μm, more preferably becomes less than or equal to 0.17 μm, further more preferably becomes less than or equal to 0.03 μm.

For the grinding, a mill machine or cracking machine such as a ball mill or a bead mill, a jet mill, a vibration filter, ultrasonic waves, or the like can be used. In the case of using a bead mill, the metal oxide powder can be grounded to several tens of nanometers. In the case of using a jet mill, entry of an unintended element can be suppressed. Note that this grinding step in Step S102 may be performed between collecting precipitation of a metal hydroxide in Step S101 and baking the metal hydroxide.

Next, in Step S103, first classification is performed on the metal oxide powder obtained in Step S102. Subsequently, in Step S104, second classification is performed on the metal oxide powder on which the first classification is performed.

Coarse grains are removed by one of the first classification and the second classification and fine grains are removed by the other, so that the metal oxide powder with uniform grain size can be obtained. Specifically, the standard deviation of the grain sizes of the crystal grains is preferably less than or equal to the average grain size of the crystal grains, more preferably less than or equal to ½ of, further more preferably less than or equal to ⅕ of the average grain size of the crystal grains.

As a classification method, any of a dry method, a wet method, and a screening method may be used. The screening method enables classification of even fine particles with less than or equal to 1 μm with high accuracy and has a cost advantage. Classification using a centrifugal precipitator or a hydraulic cyclone, which is a wet classification, has advantages of having a high processing ability and a good classification performance.

Next, in Step S105, the metal oxide powder obtained in Step S103 and Step S104 is mixed. Here, an indium oxide powder, a gallium oxide powder, and a zinc oxide powder are mixed.

Next, in Step S106, the powder obtained in Step S105 is shaped into a target shape and sintered.

There is no particular limitation on a shaping method, and a known method can be employed. Sintering is preferably performed at a temperature higher than or equal to 300° C. and lower than 1250° C. When the sintering temperature is lower than 300° C., there is a concern that crystallization from crystals of indium oxide, gallium oxide, and zinc oxide which are the raw material to an indium-gallium-zinc oxide do not progress sufficiently. Further, when the sintering temperature is higher than or equal to 1250° C., there is a concern that the grain sizes of the crystal grains included in the target become excessively large.

Hot press sintering is preferably performed because a sputtering target with small air gap and high density is easily manufactured even at a relatively low sintering temperature.

Next, in Step S107, the target obtained in Step S106 is subjected to finishing treatment. As the finishing treatment, surface grinding, bonding to a backing plate, or the like can be performed.

Through the above process, the target 100 including a polycrystalline metal oxide according to one embodiment of the present invention can be manufactured.

### Embodiment 2

In this embodiment, a target including a metal oxide having a plurality of crystal regions in which c-axes are aligned perpendicularly to a surface, according to one embodiment of the present invention is described.

In this specification and the like, a metal oxide having a plurality of crystal regions in which c-axes are aligned perpendicularly to a surface refers to a c-axis aligned crystalline (CAAC) metal oxide. A target having a plurality of crystal regions in which c-axes are aligned perpendicularly to a surface refers to a CAAC target. A metal oxide film having a plurality of crystal regions in which c-axes are aligned perpendicularly to a surface refers to a CAAC metal oxide film.

The CAAC metal oxide film is one of metal oxide films including a plurality of crystal parts, and most of the crystal parts each fit inside a cube whose one side is less than 100 nm. Thus, there is a case where a crystal part included in the CAAC metal oxide film fits inside a cube whose one side is less than 10 nm, less than 5 nm, or less than 3 nm.

In a transmission electron microscope (TEM) image of the CAAC metal oxide film, a boundary between crystal parts, that is, a grain boundary is not clearly observed. Thus, in the CAAC metal oxide film, a reduction in electron mobility due to the grain boundary is less likely to occur.

According to the TEM image of the CAAC metal oxide film observed in a direction substantially parallel to a sample surface (cross-sectional TEM image), metal atoms are arranged in a layered manner in the crystal parts. Each metal atom layer has a morphology reflected by a surface over which the CAAC metal oxide film is formed (hereinafter, a surface over which the CAAC metal oxide film is formed is referred to as a formation surface) or a top surface of the CAAC metal oxide film, and is arranged in parallel to the formation surface or the top surface of the CAAC metal oxide film.

On the other hand, according to the TEM image of the CAAC metal oxide film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC metal oxide film.

A CAAC metal oxide film is subjected to structural analysis with an X-ray diffraction (XRD) apparatus. For example, when the CAAC metal oxide film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC metal oxide film have c-axis alignment, and that the c-axes are aligned in a direction substantially perpendicular to the formation surface or the top surface of the CAAC metal oxide film.

On the other hand, when the CAAC metal oxide film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal metal oxide film of InGaZnO₄, six peaks appear. The six peaks are derived from crystal planes equivalent to the (110) plane. On the other hand, in the case of a CAAC metal oxide film, a peak is not clearly observed even when φ scan is performed with 2θ fixed at around 56°.

According to the above results, in the CAAC metal oxide film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC metal oxide film or is formed through crystallization treatment such as heat treatment. As described above, the c-axis of the crystal is aligned in a direction parallel to a normal vector of a formation surface or a normal vector of a top surface. Thus, for example, in the case where a shape of the CAAC metal oxide film is changed by etching or the like, the c-axis might not be necessarily parallel to a normal vector of a formation surface or a normal vector of a top surface of the CAAC metal oxide film.

Further, the degree of crystallinity in the CAAC metal oxide film is not necessarily uniform. For example, in the case where crystal growth leading to the CAAC metal oxide film occurs from the vicinity of the top surface of the film, the degree of the crystallinity in the vicinity of the top surface is higher than that in the vicinity of the formation surface in some cases. Further, when an impurity is added to the CAAC metal oxide film, the crystallinity in a region to which the impurity is added is changed, and the degree of crystallinity in the CAAC metal oxide film varies depending on regions.

Note that when the CAAC metal oxide film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC metal oxide film. It is preferable that in the CAAC metal oxide film, a peak of 2θ appear at around 31° and a peak of 2θ do not appear at around 36°.

The CAAC metal oxide film is a metal oxide film having a low impurity concentration. The impurity means an element other than main components of the metal oxide film, such as hydrogen, carbon, silicon, or a transition metal element. In particular, an element (e.g., silicon) having higher strength of bonding to oxygen than a metal element included in the metal oxide film takes oxygen away in the metal oxide film to disrupt the atomic arrangement in the metal oxide film, which causes a lowering of the crystallinity of the metal oxide film. A heavy metal such as iron or nickel, argon, carbon dioxide, or the like has a large atomic radius (or molecular radius), and thus disrupts the atomic arrangement in the metal oxide film when included in the metal oxide film, which causes a lowering of the crystallinity of the metal oxide film. Note that the impurity included in the metal oxide film serves as a carrier trap or a carrier generation source in some cases.

The CAAC metal oxide film is a metal oxide film having a low density of defect states. For example, oxygen vacancies in the metal oxide film serve as carrier traps or serve as carrier generation sources when hydrogen is captured therein.

The state in which impurity concentration is low and density of defect states is low (few oxygen vacancies) is referred to as “highly purified intrinsic” or “substantially highly purified intrinsic”. A highly purified intrinsic or substantially highly purified intrinsic metal oxide film has few carrier generation sources, and thus has a low carrier density. Thus, a transistor including the metal oxide film rarely has a negative threshold voltage (rarely has normally-on characteristics). A highly purified intrinsic or substantially highly purified intrinsic metal oxide film has few carrier traps. Thus, the transistor including the metal oxide film has a small variation in electric characteristics and accordingly has high reliability. Charges trapped by the carrier traps in the metal oxide film take a long time to be released and may behave like fixed charge. Thus, the transistor including the metal oxide film with a high impurity concentration and a high density of defect states has unstable electric characteristics in some cases.

With the use of the CAAC metal oxide film in a transistor, variation in the electric characteristics of the transistor due to irradiation with visible light or ultraviolet light is small.

### <CAAC Target>

The target including a metal oxide having the plurality of crystal regions in which c-axes are aligned perpendicularly to the surface, which is one embodiment of the present invention, preferably has an average projected area diameter of the crystal regions of greater than or equal to 1 nm and less than or equal to 20 nm.

The standard deviation of the projected area diameters of the crystal regions is preferably less than or equal to the average projected area diameter, more preferably less than or equal to ½ of, further more preferably less than or equal to ⅕ of the average projected area diameter. The average projected area diameter of 68% of the crystal regions is preferably two times or less, more preferably 0.5 to 1.5 times, further more preferably 0.8 to 1.2 times as large as the average projected area diameter.

The composition of the metal oxide can be determined as appropriate depending on a desired metal oxide film. Description of the target including the polycrystalline metal oxide, which is made in Embodiment 1, can be referred to for a specific composition.

### <Method for Manufacturing CAAC Target>

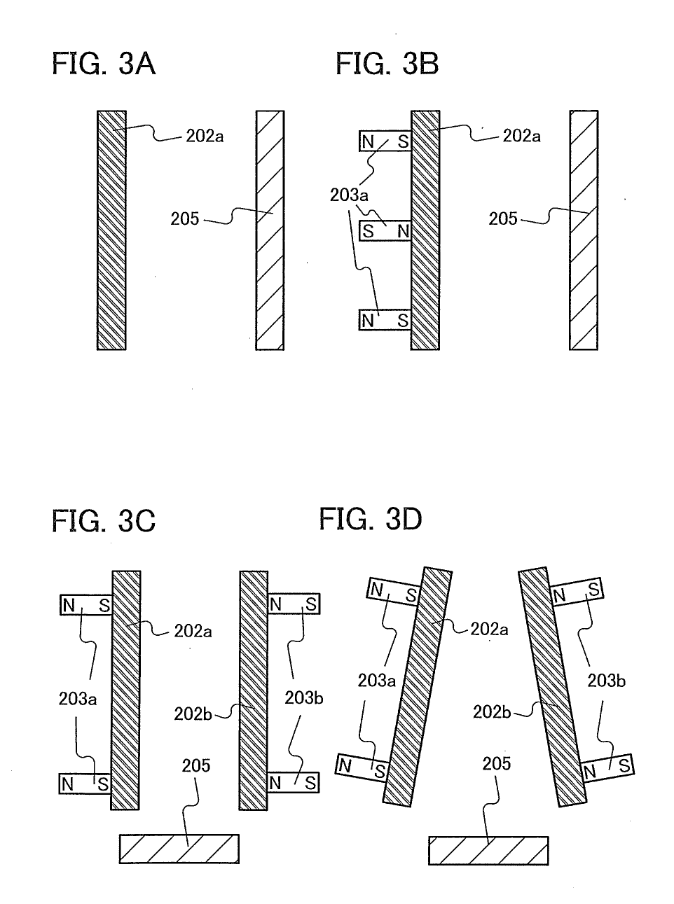

An example of a method for manufacturing a target including a metal oxide having a plurality of crystal regions in which c-axes are aligned perpendicularly to a surface is described below with reference to FIGS. 3A to 3D. The target including the metal oxide having the plurality of crystal regions in which c-axes are aligned perpendicularly to the surface can be manufactured by a sputtering method, for example.

In the case where the target is manufactured by a sputtering method, as illustrated in FIG. 3A, a known target or the target including the polycrystalline metal oxide, which is described in Embodiment 1, is provided as a target 202a. A target 205 over which a metal oxide having a plurality of crystal regions in which c-axes are aligned perpendicularly to a surface is deposited is provided so as to face the target 202a. By depositing a metal oxide of the target 202a over the target 205, the target 205 including a metal oxide having a plurality of crystal regions in which c-axes are aligned perpendicularly to a surface is manufactured.

By keeping the target 205 at a high temperature when a metal oxide is deposited by a sputtering method, the concentration of impurities which might be contained in the metal oxide deposited over the target 205 can be reduced. The temperature at which the target 205 is heated may be higher than or equal to 150° C. and lower than or equal to 500° C., preferably higher than or equal to 200° C. and lower than or equal to 350° C. By heating the target 205 at a high temperature in the deposition, the crystallinity of a metal oxide film formed over the target 205 can be increased.

In addition, it is preferable that the metal oxide be deposited in an oxidation atmosphere or an inert atmosphere. Note that the oxidation atmosphere refers to an atmosphere containing an oxidation gas. The oxidation gas is oxygen, ozone, nitrous oxide, or the like, and it is preferable that the oxidation gas do not contain water, hydrogen, and the like. For example, the purity of oxygen, ozone, or nitrous oxide to be introduced to a heating apparatus is greater than or equal to 8N (99.999999%), preferably greater than or equal to 9N (99.9999999%). The oxidation atmosphere may contain a mixed gas of an oxidation gas and an inert gas. In that case, the atmosphere contains an oxidation gas at a concentration of at least higher than or equal to 10 ppm. Note that the inert atmosphere refers to an atmosphere which contains an inert gas such as nitrogen or a rare gas or an atmosphere which does not contain a reactive gas such as an oxidation gas. Specifically, in an inert atmosphere, the concentration of a reactive gas such as an oxidation gas is lower than 10 ppm. Note that the pressure of the oxidation atmosphere or the inert atmosphere may be a reduced pressure of lower than or equal to 100 Pa, lower than or equal to 10 Pa, or lower than or equal to 1 Pa. The deposition in an oxidation atmosphere enables increase in the crystallinity of a metal oxide film formed over the target 205.

Further, as illustrated in FIG. 3B, a crystalline metal oxide film may be formed over the target 205 by providing a magnet 203a on the target 202a and employing a magnetron sputtering method. Although in FIG. 3B, two magnets 203a are placed so that S-poles thereof are in contact with the target 202a, the placement is not limited to this and the polarities of the magnets 203a can be changed as appropriate.

As illustrated in FIG. 3C, a crystalline metal oxide film may be formed over the target 205 by providing the target 202a and the target 202b so as to face each other and employing a facing-target-type sputtering method.

As illustrated in FIG. 3D, in a facing-target-type sputtering method, the target 202a provided with the magnet 203a and the target 202b provided with a magnet 203b may be arranged to be inclined. By arrangement illustrated in FIG. 3D, the deposition rate of the metal oxide film deposited over the target 205 can be increased.

Through the above process, a target including a metal oxide having a plurality of crystal regions in which c-axes are aligned perpendicularly to a surface, which is one embodiment of the present invention, can be manufactured.

### Embodiment 3

In this embodiment, a method for forming a metal oxide film using the polycrystalline target described in Embodiment 1 is described in detail. Although a metal oxide including indium, gallium, and zinc (hereinafter referred to as an In—Ga—Zn oxide) is described in this embodiment, the following description can also be referred to for a target having another composition.

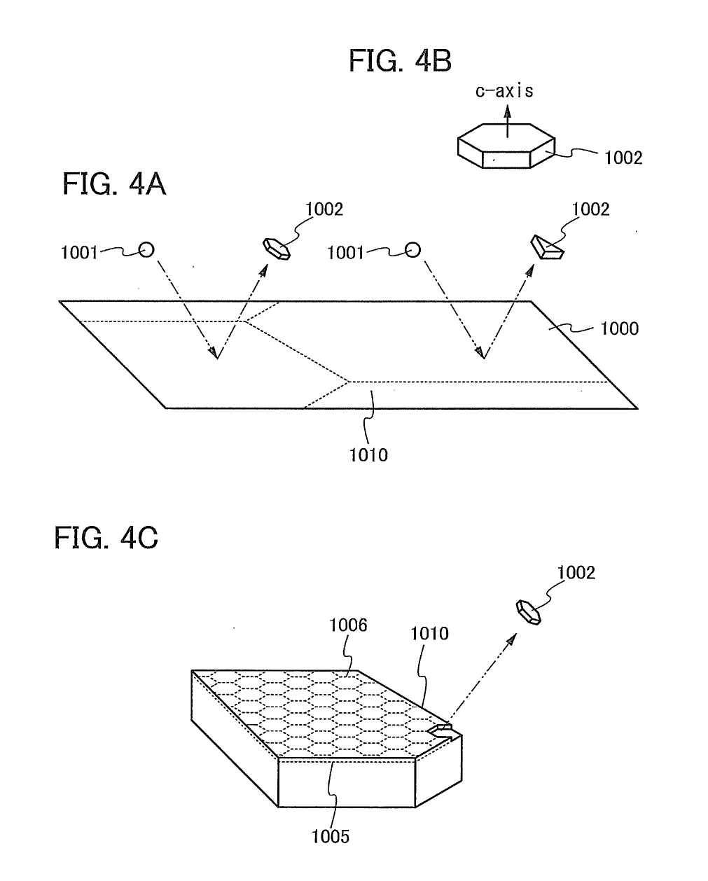

FIG. 4A is a schematic view illustrating a situation where an ion 1001 collides with a target 1000 and a sputtered particle 1002 having crystallinity is generated. The target 1000 in FIG. 4A is the target including the polycrystalline metal oxide described in Embodiment 1 and includes a crystal grain 1010. The crystal grain 1010 has an average grain size of greater than or equal to 0.1 μm and less than or equal to 3 μm and a standard deviation of less than or equal to the average grain size.

As the ion 1001, an oxygen cation can be used. Further, in addition to the oxygen cation, an argon cation may be used. Instead of the argon cation, a cation of another rare gas may be used. With the use of the oxygen cation as the ion 1001, plasma damage in the deposition can be alleviated. Thus, when the ion 1001 collides with the surface of the target 1000, a lowering in crystallinity of the target 1000 can be suppressed or a change of the target 1000 into an amorphous state can be suppressed.

FIG. 4C illustrates a detailed situation where the sputtered particle 1002 is separated from the crystal grain 1010. According to FIG. 4C, the crystal grain 1010 has a cleavage plane 1005 parallel to a surface of the sputtering target 1000. The crystal grain 1010 has a portion 1006 where an interatomic bond is weak, and the portion 1006 is shown by a dotted line. When the ion 1001 collides with the crystal grain 1010, an interatomic bond of the portion 1006 where an interatomic bond is weak is cut. Accordingly, the sputtered particle 1002 is separated in a flat-plate form by being cut out along the cleavage plane 1005 and the portion 1006 where an interatomic bond is weak. Note that the projected area diameter of the sputtered particle 1002 is greater than or equal to 1/3000 and less than or equal to 1/20, preferably greater than or equal to 1/1000 and less than or equal to 1/30 of the average grain size of the crystal grains 1010. When the diameters of the crystal grains 1010 at this time are small and uniform, projected area diameters of the sputtered particles 1002 can be smaller and uniform.

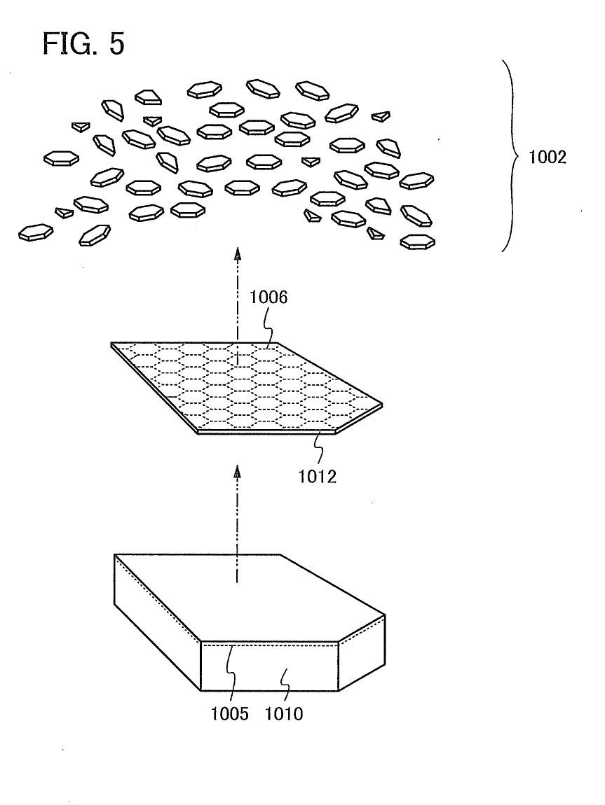

Alternatively, part of the crystal grain 1010 is separated as a particle 1012 from the cleavage plane 1005. Then, when the particle 1012 is exposed to plasma, bonds start to be cut at the portion 1006 where an interatomic bond is weak by an effect of plasma, and a plurality of sputtered particles 1002 are generated (see FIG. 5).

Note that the sputtered particle 1002 may have a hexagonal prism shape in which the cleavage plane 1005 is a flat plane parallel to an a-b plane. In such a case, a direction perpendicular to a hexagonal plane is a c-axis direction of the crystal (see FIG. 4B). Note that the sputtered particle 1002 may have a triangular prism shape in which the cleavage plane is a flat plane parallel to an a-b plane. Alternatively, the sputtered particle 1002 may have a polygonal prism shape different from the above. Note that the sputtered particle 1002 has a flat plane whose equivalent circle diameter is greater than or equal to 1 nm and less than or equal to 15 nm, or greater than or equal to 2 nm and less than or equal to 10 nm.

It is preferable that the separated sputtered particles 1002 be positively charged. There is no particular limitation on a timing of when the sputtered particle 1002 is positively charged, but it is preferably positively charged by receiving an electric charge when the ion 1001 collides. Alternatively, in the case where plasma is generated, the sputtered particle 1002 is preferably exposed to plasma to be positively charged. Further alternatively, the ion 1001 which is an oxygen cation is preferably bonded to a surface of the sputtered particle 1002, whereby the sputtered particle 1002 is positively charged.

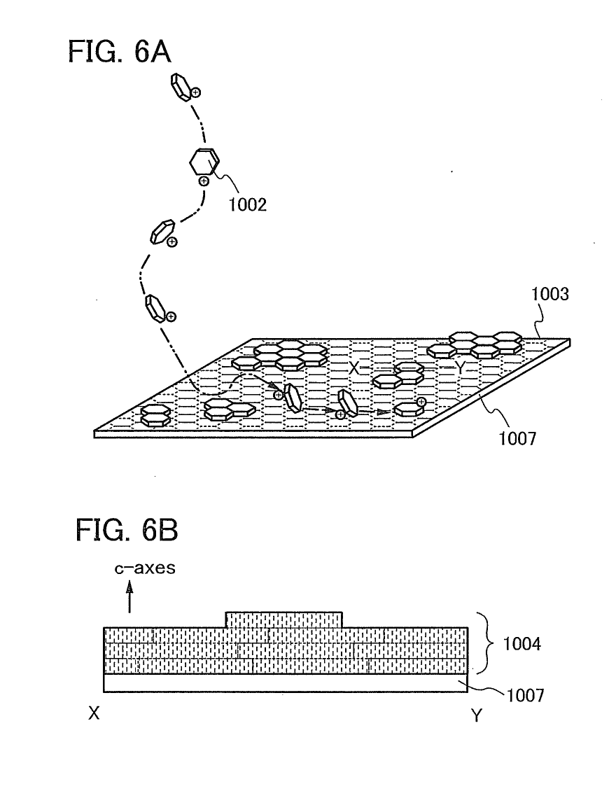

A situation where a sputtered particle is deposited on a deposition surface is described with reference to FIGS. 6A and 6B. Note that in FIGS. 6A and 6B, sputtered particles which have been already deposited are shown by dotted lines.

In FIG. 6A, a deposition surface 1003 has a surface on which the sputtered particles 1002 are deposited. Note that an amorphous film 1007 is formed on the lower side of the deposition surface 1003. As shown in FIG. 6A, the sputtered particle 1002 is positively charged, and accordingly the sputtered particle 1002 is deposited on a region where other sputtered particles 1002 have not been deposited yet. This is because the sputtered particles 1002 that are positively charged repel each other.

A metal oxide film which is obtained by deposition has a uniform thickness and a uniform crystal orientation.

In the case where the sizes of the sputtered particles 1002 are uniform, speed at which the particles reach the deposition surface 1003 from the target can be uniform. Further, in the case where the sizes of the sputtered particles 1002 are uniform, the particles are easily spread over the deposition surface. Thus, projected area diameters of crystal regions of a metal oxide film obtained by depositing the sputtered particles 1002 can be made more uniform.

FIG. 6B is a cross-sectional view taken along dashed-dotted line X-Y in FIG. 6A. A metal oxide film 1004 in which c-axes of crystals of the deposited sputtered particles 1002 are aligned in a direction perpendicular to the deposition surface 1003 is, for example, a CAAC metal oxide film.

With the use of the sputtering target in the way as described above, a metal oxide film with a uniform thickness and a uniform crystal orientation can be formed.

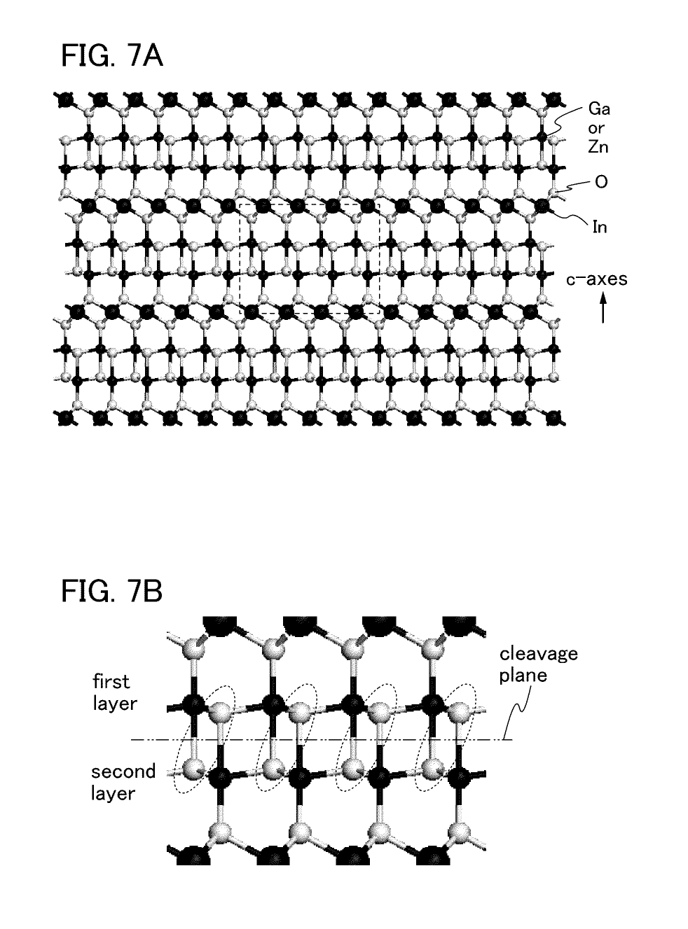

FIG. 7A illustrates an example of the crystal structure of an In—Ga—Zn oxide viewed from a direction parallel to the a-b plane. Further, FIG. 7B illustrates an enlarged portion surrounded by a dashed line in FIG. 7A.

For example, in a crystal grain of an In—Ga—Zn oxide, a cleavage plane is a plane between a first layer and a second layer as illustrated in FIG. 7B. The first layer includes a gallium atom and/or zinc atom and an oxygen atom, and the second layer includes a gallium atom and/or zinc atom and an oxygen atom. This is because oxygen atoms having negative charge in the first layer and oxygen atoms having negative charge in the second layer are close to each other (see a portion surrounded by a dotted line in FIG. 7B). Since the cleavage plane is a flat plane parallel to an a-b plane, the sputtered particle including an In—Ga—Zn oxide has a flat-plate-like shape having a flat plane parallel to an a-b plane.

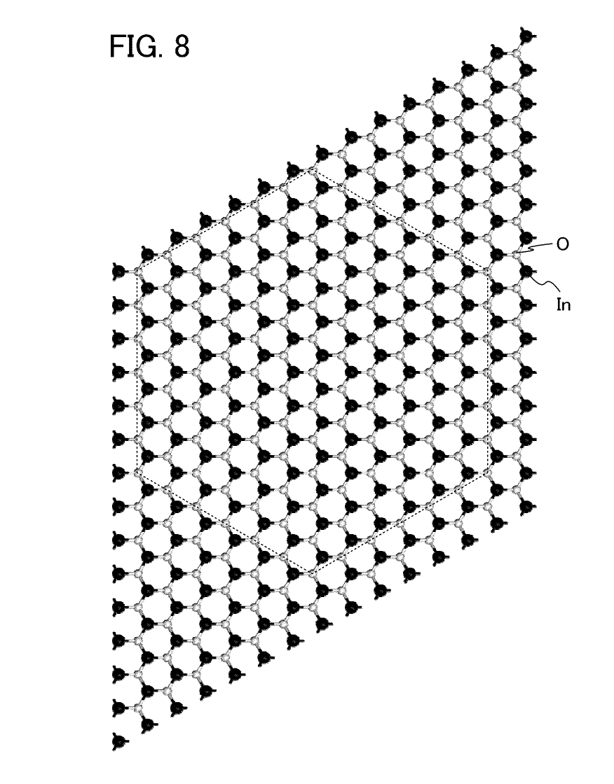

FIG. 8 illustrates an example of a crystal structure of an In—Ga—Zn oxide viewed from a direction perpendicular to an a-b plane of the crystal. Note that in FIG. 8, only a layer including indium atoms and oxygen atoms is extracted.

In the In—Ga—Zn oxide, a bond between an indium atom and an oxygen atom is weak and easily cut. When the bond is cut, the oxygen atom is detached, and vacancies of oxygen atoms (also referred to as oxygen vacancy) are sequentially caused as shown by a dotted line in FIG. 8. In FIG. 8, a regular hexagonal shape can be traced by connecting the oxygen vacancies by the dotted line. As described above, the crystal of the In—Ga—Zn oxide has a plurality of planes which are perpendicular to an a-b plane and generated when the bonds between indium atoms and oxygen atoms are cut.

The crystal of the In—Ga—Zn oxide is a hexagonal crystal; thus, the flat-plate-like sputtered particle is likely to have a hexagonal prism shape with a regular hexagonal plane whose internal angle is 120°. Note that the flat-plate-like sputtered particle is not limited to a hexagonal prism shape, and in some cases, it has a triangular prism shape with a regular triangular plane whose internal angle is 60° or a polygonal prism shape different from the above shapes.

Note that heat treatment is preferably performed on the deposited crystalline metal oxide film with high orientation in an oxidation atmosphere in order to reduce oxygen vacancies.

Further, also in the case where a metal oxide film is formed using the CAAC target described in Embodiment 2, almost the same steps are performed. Since the CAAC target has a plurality of crystal regions in which c-axes are aligned perpendicularly to a surface, crystalline sputtered particles 1002 are generated from the crystal regions. The method for forming a metal oxide film using a polycrystalline target can be referred to for the other steps.

By depositing sputtered particles as described in this embodiment, a crystalline metal oxide can be formed. Further, the crystalline metal oxide formed in such a manner can be a film where a clear grain boundary does not exist as in a CAAC metal oxide film. Since a grain boundary exists in a conductive or a semiconductor polycrystalline metal oxide film, there are problems such as interruption of carrier transfer at the grain boundary and precipitation of an impurity at the grain boundary. However, since a clear grain boundary does not exist in a CAAC metal oxide film, these problems do not arise; thus, the CAAC metal oxide film is suitable for a semiconductor device typified by a transistor.

The method for forming a metal oxide film in this embodiment can be employed in combination with any of the other embodiments.

### Embodiment 4

In this embodiment, a semiconductor device manufactured by applying the metal oxide described in any of Embodiments 1 to 3 to a semiconductor film of a transistor is described. A transistor including an oxide semiconductor film with high crystallinity has high reliability and small variation in electric characteristics due to irradiation with visible light or ultraviolet light and thus can be preferably used for a variety of semiconductor devices.

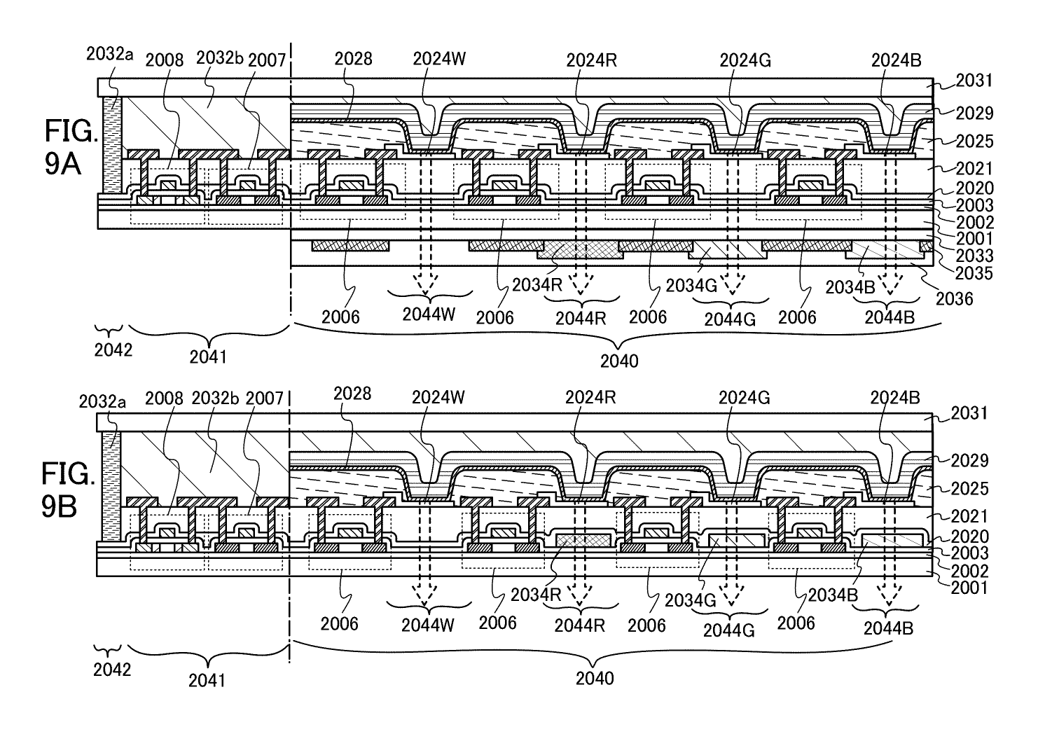

First, an active matrix light-emitting device which includes a transistor including an oxide semiconductor film with high crystallinity is described with reference to FIGS. 9A and 9B.

FIGS. 9A and 9B show examples of a light-emitting device which realizes full color display with the use of a coloring layer and the like. In FIG. 9A, transistors 2006, 2007, and 2008 which include oxide semiconductor films with high crystallinity, a substrate 2001, a base insulating film 2002, an insulating film 2003, a first interlayer insulating film 2020, a second interlayer insulating film 2021, a peripheral portion 2042, a pixel portion 2040, a driver circuit portion 2041, first electrodes 2024W, 2024R, 2024G, and 2024B of light-emitting elements, a partition wall 2025, an EL layer 2028, a second electrode 2029 of the light-emitting elements, a sealing substrate 2031, a sealant 2032a, a sealant 2032b, and the like are illustrated. The sealant 2032b can be mixed with a desiccant. Further, coloring layers (a red coloring layer 2034R, a green coloring layer 2034G, and a blue coloring layer 2034B) are provided on a transparent base material 2033. Further, a black layer (a black matrix) 2035 may be additionally provided. The transparent base material 2033 provided with the coloring layers and the black layer is positioned and fixed to the substrate 2001. Note that the coloring layers and the black layer are covered with an overcoat layer 2036. In this embodiment, light emitted from some of the light-emitting layers does not pass through the coloring layers, while light emitted from the others of the light-emitting layers passes through the coloring layers. Since light which does not pass through the coloring layers is white and light which passes through any one of the coloring layers is red, blue, or green, an image can be displayed using pixels of the four colors.

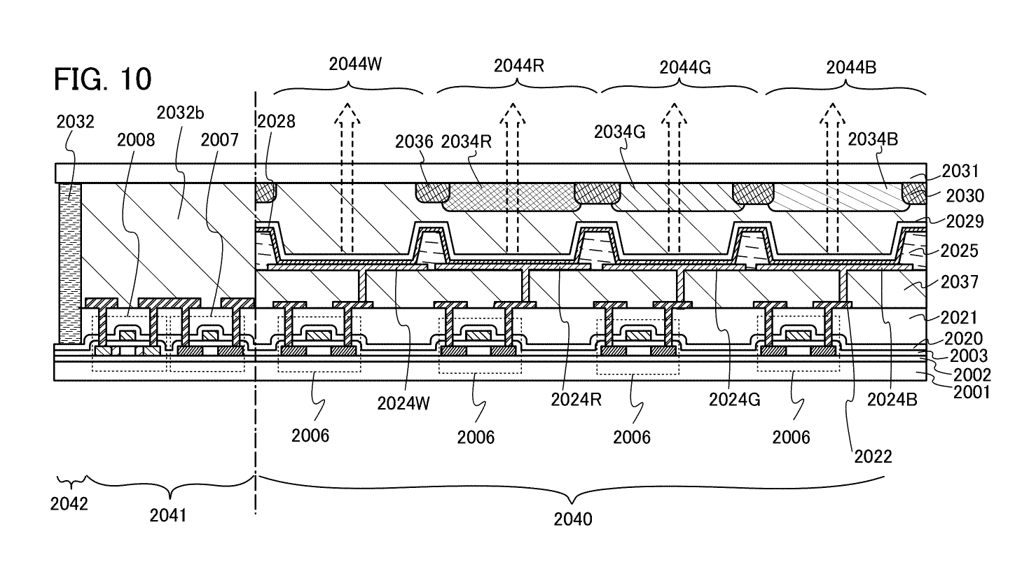

The above-described light-emitting device is a light-emitting device having a structure in which light is extracted from the substrate 2001 side where the TFTs are formed (a bottom emission structure), but may be a light-emitting device having a structure in which light is extracted from the sealing substrate 2031 side (a top emission structure). FIG. 10 is a cross-sectional view of a light-emitting device having a top emission structure. In this case, a substrate which does not transmit light can be used as the substrate 2001. The process up to the step of forming a connection electrode which connects the TFT and the anode of the light-emitting element is performed in a manner similar to that of the light-emitting device having a bottom emission structure. Then, a third interlayer insulating film 2037 is formed to cover an electrode 2022. The third interlayer insulating film 2037 may have a planarization function. The third interlayer insulating film 2037 can be formed using a material similar to that of the second interlayer insulating film 2021, and can alternatively be formed using any other known material. In addition, a space between the light-emitting elements and the sealing substrate 2031 is filled with the sealant 2032b, so that the light extraction efficiency can be improved.

The first electrodes 2024W, 2024R, 2024G, and 2024B of the light-emitting elements each serve as an anode here, but may serve as a cathode. Further, in the case of a light-emitting device having a top emission structure as illustrated in FIG. 10, the first electrodes are preferably reflective electrodes. The EL layer 2028 is formed to have a structure with which white light emission can be obtained. As the structure with which white light emission can be obtained, in the case where two EL layers are used, a structure with which blue light is obtained from a light-emitting layer in one of the EL layers and orange light is obtained from a light-emitting layer of the other of the EL layers; a structure in which blue light is obtained from a light-emitting layer of one of the EL layers and red light and green light are obtained from a light-emitting layer of the other of the EL layers; and the like can be given. Further, in the case where three EL layers are used, red light, green light, and blue light are obtained from respective light-emitting layers, so that a light-emitting element which emits white light can be obtained.

The coloring layers are each provided in a light path through which light from the light-emitting element passes to the outside of the light-emitting device. In the case of the light-emitting device having a bottom emission structure as illustrated in FIG. 9A, the coloring layers 2034R, 2034G, and 2034B can be provided on the transparent base material 2033 and then fixed to the substrate 2001. The coloring layers may be provided between the insulating film 2003 and the first interlayer insulating film 2020 as illustrated in FIG. 9B. In the case of a light-emitting device having a top emission structure as illustrated in FIG. 10, sealing can be performed with the sealing substrate 2031 on which the coloring layers (the red coloring layer 2034R, the green coloring layer 2034G, and the blue coloring layer 2034B) are provided. The sealing substrate 2031 may be provided with the black layer (the black matrix) 2035 which is positioned between pixels. The coloring layers (the red coloring layer 2034R, the green coloring layer 2034G, and the blue coloring layer 2034B) and the black layer (the black matrix) 2035 may be covered with the overcoat layer 2036. Note that a light-transmitting substrate is used as the sealing substrate 2031.

When voltage is applied between the pair of electrodes of the thus obtained light-emitting element, a white light-emitting region 2044W can be obtained. In addition, by using the coloring layers, a red light-emitting region 2044R, a blue light-emitting region 2044B, and a green light-emitting region 2044G can be obtained. The light-emitting device in this embodiment includes the oxide semiconductor film with high crystallinity described in Embodiment 3; thus, a highly reliable light-emitting device can be obtained.

Further, although an example in which full color display is performed using four colors of red, green, blue, and white is shown here, there is no particular limitation and full color display using three colors of red, green, and blue may be performed.

Next, examples of electronic devices each of which includes, as a part thereof, a transistor including the oxide semiconductor film with high crystallinity described in Embodiment 3 are described.

Examples of the electronic device to which the above transistor is applied include television devices (also referred to as TV or television receivers), monitors for computers and the like, cameras such as digital cameras and digital video cameras, digital photo frames, mobile phones (also referred to as cell phones or mobile phone devices), portable game machines, portable information terminals, audio reproducing devices, large game machines such as pachinko machines, and the like. Specific examples of these electronic devices are given below.

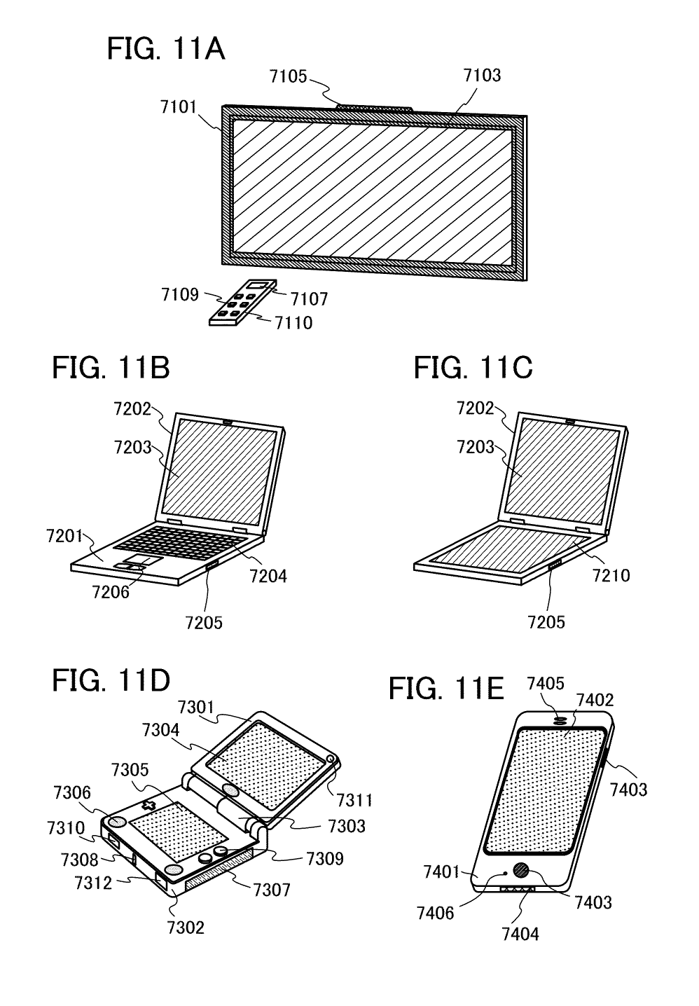

FIG. 11A illustrates an example of a television device. In the television device, a display portion 7103 is incorporated in a housing 7101. In addition, here, the housing 7101 is supported to a wall by a fixing member 7105. Images can be displayed on the display portion 7103, and the display portion 7103 includes a transistor which includes the oxide semiconductor film having high crystallinity described in Embodiment 3. Thus, the television device can be a highly reliable television device.

Operation of the television device can be performed with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

FIG. 11B illustrates a computer, which includes a main body 7201, a housing 7202, a display portion 7203, a keyboard 7204, an external connection port 7205, a pointing device 7206, and the like. Note that this computer is manufactured by using a transistor which includes the oxide semiconductor film with high crystallinity described in Embodiment 3. The computer illustrated in FIG. 11B may have a structure illustrated in FIG. 11C. The computer illustrated in FIG. 11C is provided with a second display portion 7210 instead of the keyboard 7204 and the pointing device 7206. The second display portion 7210 is a touch screen, and input can be performed by operation of display for input on the second display portion 7210 with a finger or a dedicated pen. The second display portion 7210 can also display images other than the display for input. The display portion 7203 may be also a touch screen. Connecting the two screens with a hinge can prevent troubles; for example, the screens can be prevented from being cracked or broken while the computer is being stored or carried. Since the computer includes the transistor which includes the oxide semiconductor film with high crystallinity described in Embodiment 3, the computer can be a highly reliable computer.

FIG. 11D illustrates a portable game machine having two housings, a housing 7301 and a housing 7302, which are connected with a joint portion 7303 so that the portable game machine can be opened or folded. The housing 7301 incorporates a display portion 7304 and the housing 7302 incorporates a display portion 7305. The display portion 7304 and the display portion 7305 each incorporate a transistor which includes the oxide semiconductor film with high crystallinity described in Embodiment 3. In addition, the portable game machine illustrated in FIG. 11D includes a speaker portion 7306, a recording medium insertion portion 7307, an LED lamp 7308, an input means (an operation key 7309, a connection terminal 7310, a sensor 7311 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), and a microphone 7312), and the like. The portable game machine illustrated in FIG. 11D has a function of reading out a program or data stored in a storage medium to display it on the display portion, and a function of sharing information with another portable game machine by wireless communication. Note that functions of the portable game machine illustrated in FIG. 11D are not limited to them, and the portable game machine can have a variety of functions. Since the above-described portable game machine incorporating the display portion 7304 and the display portion 7305 includes the transistors including the oxide semiconductor films having high crystallinity described in Embodiment 3, the portable game machine can be a highly reliable portable game machine.

FIG. 11E illustrates an example of a mobile phone. The mobile phone is provided with a display portion 7402 incorporated in a housing 7401, operation buttons 7403, an external connection port 7404, a speaker 7405, a microphone 7406, and the like. Note that the mobile phone illustrated in FIG. 11E includes a transistor which includes the oxide semiconductor film with high reliability described in Embodiment 3. Thus, the mobile phone can be a highly reliable mobile phone.

When the display portion 7402 of the mobile phone illustrated in FIG. 11E is touched with a finger or the like, data can be input into the mobile phone. In this case, operations such as making a call and creating an e-mail can be performed by touching the display portion 7402 with a finger or the like.

There are mainly three screen modes of the display portion 7402. The first mode is a display mode mainly for displaying an image. The second mode is an input mode mainly for inputting information such as characters. The third mode is a display-and-input mode in which two modes of the display mode and the input mode are combined.

For example, in the case of making a call or creating an e-mail, a character input mode mainly for inputting characters is selected for the display portion 7402 so that characters displayed on a screen can be input. In this case, it is preferable to display a keyboard or number buttons on almost the entire screen of the display portion 7402.

When a detection device including a sensor for detecting inclination, such as a gyroscope or an acceleration sensor, is provided inside the mobile phone, display on the screen of the display portion 7402 can be automatically changed by determining the orientation of the mobile phone (whether the mobile phone is placed horizontally or vertically for a landscape mode or a portrait mode).

The screen modes are switched by touch on the display portion 7402 or operation with the operation buttons 7403 of the housing 7401. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal detected by an optical sensor in the display portion 7402 is detected, the screen mode may be controlled so as to be switched from the input mode to the display mode.

The display portion 7402 may function as an image sensor. For example, an image of a palm print, a fingerprint, or the like is taken by touch on the display portion 7402 with the palm or the finger, whereby personal authentication can be performed. Further, by providing a backlight or a sensing light source which emits a near-infrared light in the display portion, an image of a finger vein, a palm vein, or the like can be taken.

Note that the structure described in this embodiment can be combined with any of the structures described in Embodiments 1 to 3 as appropriate.

### Example

In this example, a metal oxide having a plurality of crystal regions in which c-axes are aligned is actually manufactured, and results of evaluating its crystallinity are described.

In this example, as the metal oxide having the plurality of crystal regions in which c-axes are aligned, a metal oxide including indium, gallium, and zinc and has a composition of indium:gallium:zinc=1:1:1 (atomic ratio) was used. The metal oxide was sliced so as to be observed from a surface, that is, the direction perpendicular to a c-axis, and a transmission electron microscope (TEM) image and nanobeam electron diffraction patterns were obtained.

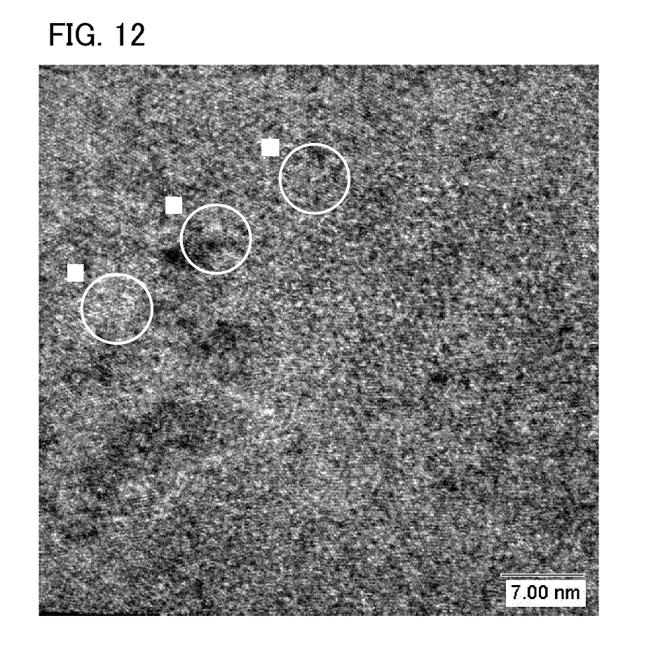

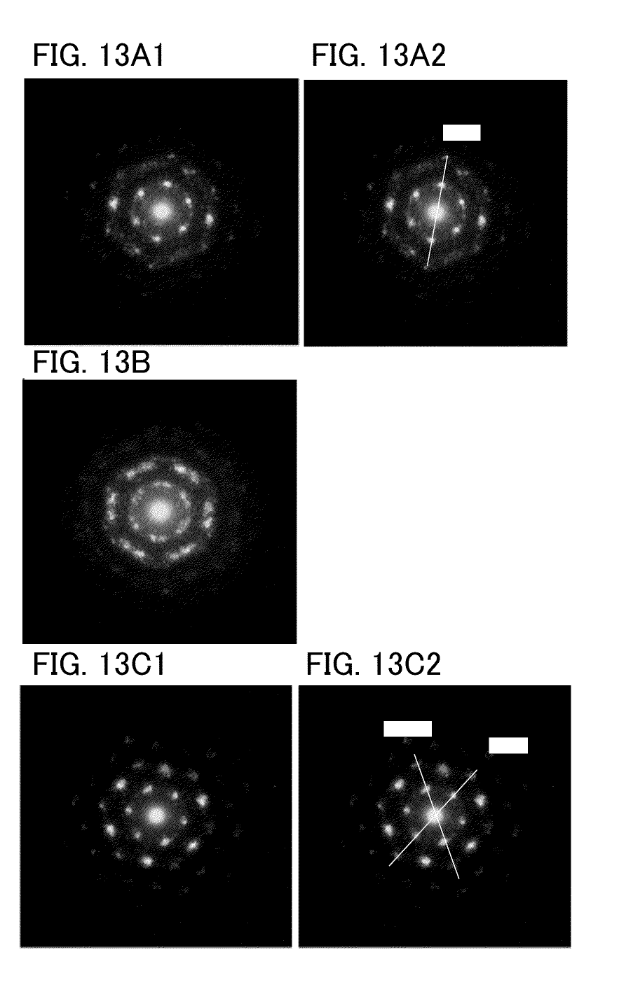

FIG. 12 is a TEM image, and FIGS. 13A1, 13A2, 13B, 13C1, and 13C2 are electron diffraction patterns. FIGS. 13A1, 13B, and 13C1 are electron diffraction patterns of regions denoted by circles A, B, and C with white lines in FIG. 12. FIG. 13A2 shows the symmetry axis in FIG. 13A1 and an angle of the symmetry axis when the direction of twelve o'clock is set to 0° from the center of the electron diffraction pattern and an angle in a clockwise direction is set to a positive angle. Similarly, FIG. 13C2 shows the symmetry axes and angles in FIG. 13C1.

As shown in FIG. 12, a grain boundary is not observed between the plurality of crystal regions included in the metal oxide. For example, when the circle A and the circle C in FIG. 12 are respectively set to a first crystal region and a second crystal region, a grain boundary is not observed in a region (e.g., the circle B) between the first crystal region and the second crystal region.

From the electron diffraction patterns in FIGS. 13A1, 13A2, 13B, 13C1, and 13C2, continuous changes of the directions of the a-axes and the b-axes between the first crystal region and the second crystal region can be explained.

In the electron diffraction patterns of the first crystal region in FIG. 13A1 and the second crystal region in FIG. 13C1, dot-shaped luminescent spots having three symmetry axes were observed. This shows that the first crystal region and the second crystal region each are a crystal region in which c-axes are aligned. Note that it is known that a metal oxide including indium, gallium, and zinc is a hexagonal crystal.

As shown in FIG. 13A2, one of the symmetry axes in the first crystal region was 10.2°. As shown in FIG. 13C2, one of the symmetry axes of the second crystal region was −17.5° and the other was 42.5°. Since angles of the symmetry axes of luminescent spots (also referred to positions at which luminescent spots appear) in the first crystal region and the second crystal region are different as described above, it was found that the directions of the a-axes and b-axes in the first crystal region and the second crystal region are different in a plane.

In the electron diffraction pattern of the region between the first crystal region and the second crystal region in FIG. 13B, belt-shaped luminescent points connecting 10.2° at which the luminescent points of the first crystal region occur and −17.5° at which the luminescent points of the second crystal region occur were observed. Further, belt-shaped luminescent points were observed so as to connect 10.2° at which the luminescent points of the first crystal region occur and 42.5° at which the luminescent points of the second crystal region occur.

In a polycrystalline metal oxide having a grain boundary, it is known that when an electron diffraction pattern is obtained over the grain boundary, dot-shaped luminescent points included in the crystals are observed at the same time. However, belt-shaped luminescent points observed in FIG. 13B were not observed.

Further, in an amorphous metal oxide, it is known that when an electron diffraction pattern is obtained, a region which has high luminance concentrically appears. This is also different from the belt-shaped luminescent spots shown in FIG. 13B.

As described above, from the TEM image and the electron diffraction patterns, a grain boundary is not observed in the metal oxide having the plurality of crystal regions in which c-axes are aligned, and it was revealed that the metal oxide having the plurality of crystal regions in which c-axes are aligned is different from a polycrystalline metal oxide and an amorphous metal oxide.

This application is based on Japanese Patent Application serial no. 2012-178380 filed with Japan Patent Office on Aug. 10, 2012, the entire contents of which are hereby incorporated by reference.

What is claimed is:

1. A sputtering target comprising a polycrystalline metal oxide,
wherein an average of grain sizes of crystal grains is greater than or equal to 0.1 μm and less than or equal to 3 μm, and
wherein a standard deviation of the grain sizes of the crystal grains is less than or equal to ½ of the average of the grain sizes of the crystal grains.

2. The sputtering target according to claim 1, wherein the polycrystalline metal oxide comprises indium, gallium, and zinc.

3. The sputtering target according to claim 2, wherein a proportion of the gallium is over 20 atomic % among the indium, the gallium, and the zinc in the polycrystalline metal oxide.

4. The sputtering target according to claim 1, wherein the crystal grains are hexagonal crystals.

5. The sputtering target according to claim 1, wherein a silicon content and a carbon content each are less than 1×10¹⁸ atoms/cm³ in the sputtering target.

6. A sputtering target comprising a metal oxide comprising a plurality of crystal regions in which c-axes are aligned perpendicularly to a surface,
wherein an average of projected area diameters of the plurality of crystal regions is greater than or equal to 1 nm and less than or equal to 20 nm, and
wherein a standard deviation of the projected area diameters of the plurality of crystal regions is less than or equal to ½ of the average of the projected area diameters.

7. The sputtering target according to claim 6,
wherein when an electron diffraction pattern of a first crystal region, an electron diffraction pattern of a second crystal region, and an electron diffraction pattern of a crystal region between the first crystal region and the second crystal region are compared among the plurality of crystal regions, in the crystal region between the first crystal region and the second crystal region, belt-shaped luminescent spots are observed in a region which connects a luminescent spot in the first crystal region and a luminescent spot in the second crystal region, and
wherein the first crystal region and the second crystal region have different directions of a-axes and b-axes.

8. The sputtering target according to claim 6, wherein the metal oxide comprises indium, gallium, and zinc.

9. The sputtering target according to claim 8, wherein a proportion of the gallium is over 20 atomic % among the indium, the gallium, and the zinc in the metal oxide.

10. The sputtering target according to claim 6, wherein the plurality of crystal regions comprise hexagonal crystals.

11. The sputtering target according to claim 6, wherein a silicon content and a carbon content each are less than 1×10¹⁸ atoms/cm³ in the sputtering target.

12. A method for using a sputtering target comprising:
a polycrystalline metal oxide
wherein an average of grain sizes of crystal grains is greater than or equal to 0.1 μm and less than or equal to 3 μm and a standard deviation of the grain sizes of the crystal grains is less than or equal to ½ of the average of the grain sizes of the crystal grains, or
a method for using a sputtering target comprising:
a metal oxide comprising a plurality of crystal regions in which c-axes are aligned perpendicularly to a surface,
wherein an average of projected area diameters of the plurality of crystal regions is greater than or equal to 1 nm and less than or equal to 20 nm and a standard deviation of the projected area diameters of the crystal regions is less than or equal to ½ of the average of the projected area diameters,
one of the methods comprising the steps of:
generating a flat-plate-like sputtered particle with a projected area diameter of greater than or equal to 1 nm and less than or equal to 20 nm by collision of an ion, and
depositing the sputtered particle.

13. The method for using the sputtering target according to claim 12, wherein the metal oxide comprises indium, gallium, and zinc.

14. The method for using the sputtering target according to claim 13, wherein a proportion of the gallium is over 20 atomic % among the indium, the gallium, and the zinc in the metal oxide.
